(19) United States
(12) Patent Application Publication
(10) Pub. No.: US 2026/0157070 A1
(43) Pub. Date: Jun. 4, 2026

(54) DISPLAY PANEL AND DISPLAY DEVICE

(71) Applicants: Mianyang HKC Optoelectronics Technology Co., Ltd., Mianyang (CN); HKC Corporation Limited, Shenzhen (CN)

(72) Inventors: QIN LIANG, Mianyang (CN); Yangling Tang, Mianyang (CN); Zhisheng Xie, Mianyang (CN); Xiufeng Zhou, Mianyang (CN); Pei Xu, Mianyang (CN)

(21) Appl. No.: 19/384,939

(22) Filed: Nov. 10, 2025

(30) Foreign Application Priority Data
Nov. 29, 2024 (CN) 202411735698.1

(51) Int. Cl. H10K 59/38; H10K 59/122; H10K 59/40; H10K 59/80

(52) U.S. Cl. CPC H10K 59/38; H10K 59/122; H10K 59/873; H10K 59/40

(57) ABSTRACT

A display panel and a display device are disclosed. The display panel includes a substrate, a pixel driving layer, a pixel defining layer, multiple light-emitting elements, an encapsulation layer, and a color filter layer. The encapsulation layer defines a first groove at a position corresponding to each aperture region. The color filter layer includes multiple color filter pieces and multiple light-shielding pieces. The color filter pieces are respectively disposed in the first grooves. The color filter pieces include color filter pieces of at least two different colors. The light-shielding pieces are disposed in the non-aperture regions. The light-shielding pieces are each formed by stacking the color filter pieces of different colors.

### CROSS-REFERENCE TO RELATED APPLICATIONS

The present application claims the priority and benefit of Chinese patent application number 2024117356981, titled “Display Panel and Display Device” and filed Nov. 29, 2024 with China National Intellectual Property Administration, the entire contents of which are incorporated herein by reference.

### TECHNICAL FIELD

The present application relates to the field of display technology, and more particularly relates to a display panel and a display device.

### BACKGROUND

The description provided in this section is intended for the mere purpose of providing background information related to the present application but does not necessarily constitute prior art.

With the continuous development of OLED (Organic Light-Emitting Diode) display technology, OLEDs are being increasingly applied in displays such as smartphones, tablets, computers, and televisions. OLED displays offer advantages including a thin and lightweight structure, high contrast ratio, fast response time, wide viewing angle, high brightness, and full-color capability. In order to reduce the reflection of external light within an OLED display, a mainstream solution is to attach a circular polarizer on a light-emitting surface of the OLED display. However, this approach causes significant light loss due to this circular polarizer, thereby reducing the light output efficiency. Another solution involves forming a plurality of color filter pieces on the light-emitting surface of the OLED display. The use of color filter elements improves the light output efficiency, and the provision of a black matrix (BM) can reduce the reflection of ambient light within the OLED display, while also contributing to a reduction in the overall thickness of the display panel.

However, during the fabrication of the plurality of color filter pieces on the display panel, the black matrix may affect the color filter pieces in the process of forming the plurality of color filter pieces using a color filter material after the black matrix has been formed, thereby leading to display issues associated with the color filter pieces.

### SUMMARY

It is therefore one purpose of the present application to provide a display panel and a display device, where a first groove is defined to accommodate a color filter piece, and color filter pieces of different colors are stacked to form a light-shielding piece, thereby solving the manufacturing process-related issues of the color filter piece, improving the light output efficiency of the color filter piece, and enhancing the display effect of the display panel.

The present application discloses a display panel. The display panel includes a substrate, a pixel driving layer, a pixel defining layer, a plurality of light-emitting elements, an encapsulation layer, and a color filter layer. The pixel driving layer is disposed on the substrate. The pixel defining layer is disposed on the pixel driving layer and defines a plurality of aperture regions. The plurality of light-emitting elements are arranged in an array on the pixel driving layer and are respectively disposed in the plurality of aperture regions. The encapsulation layer is disposed on the light-emitting element layer and is configured to seal the plurality of light-emitting elements. The encapsulation layer defines a first groove at a position corresponding to each of the aperture regions. The color filter layer is disposed on the encapsulation layer. The color filter layer includes a plurality of color filter pieces and a plurality of light-shielding pieces. Each of the color filter pieces is disposed within a corresponding first groove. The plurality of color filter pieces include color filter pieces of at least two different colors. The plurality of light-shielding pieces are respectively disposed in the plurality of non-aperture regions. Each of the light-shielding pieces is formed by overlapping the color filter pieces of different colors.

In some embodiments, the encapsulation layer includes an organic encapsulation layer. The first groove is defined in the organic encapsulation layer at a position corresponding to each of the aperture regions. A radial width of the first groove is greater than a radial width of the corresponding aperture region. An orthogonal projection of each of the light-shielding pieces on the substrate partially overlaps an orthogonal projection of an adjacent first groove on the substrate.

In some embodiments, the encapsulation layer further includes a first inorganic layer, the first inorganic layer being disposed on the organic encapsulation layer. A thickness of the first inorganic layer is less than a depth of the first groove. The first inorganic layer covers the first groove to form a second groove. A sidewall of the second groove is spaced from an edge of the corresponding aperture region by 5 micrometers to 20 micrometers.

In some embodiments, the display panel further includes a plurality of reflective layers. Each of the reflective layers is disposed on a side surface of a corresponding first groove. Each of the reflective layers forms an obtuse angle with a bottom surface of the corresponding first groove.

In some embodiments, the display panel further includes a touch wiring layer, the touch wiring layer being disposed on the encapsulation layer. The touch wiring layer and the reflective layer are formed of a metal material in the same manufacturing procedure.

In some embodiments, the plurality of color filter pieces include a plurality of first color filter pieces and a plurality of second color filter pieces. The plurality of first color filter pieces have a color different from that of the plurality of second color filter pieces. In each of the non-aperture regions, a first color extension piece corresponding to the plurality of first color filter pieces and a second color extension piece corresponding to the plurality of second color filter pieces are synchronously formed. The first color extension piece and the second color extension piece are stacked to form the corresponding light-shielding piece. The first color extension piece is disposed below the second color extension piece. The orthographic projections of the second color extension piece and the first color extension piece on the substrate each overlap the corresponding reflective layer.

In some embodiments, each of the first color filter pieces is a red filter piece. Each of the first color extension pieces is a red extension piece. Each of the second color filter pieces is a blue filter piece. Each of the second color extension pieces is a blue extension piece. In each of the non-aperture regions, the corresponding light-shielding piece is formed by stacking the red extension piece and the blue extension piece.

In some embodiments, the thickness of each of the red extension pieces is equal to half of the thickness of each of the red filter pieces. The thickness of each of the blue extension pieces is equal to half of the thickness of each of the blue filter pieces.

In some embodiments, a side surface of the first color extension piece adjacent to the neighboring second color filter piece forms an obtuse angle with the bottom surface of the first color extension piece.

The present application further discloses a display device including a driving circuit and the above-mentioned display panel, where the driving circuit is configured to drive the display panel for display.

In the present application, a first groove is formed in the encapsulation layer, and the color filter piece is recessed into the first groove, that is, the color filter piece is formed within the first groove. The plurality of color filter pieces respectively extend to the non-aperture region to form extension pieces, which are stacked to form the light-shielding piece, that is, the light-shielding piece is formed by extension pieces of at least two colors, thereby saving the manufacturing procedures required to form the black matrix, reducing the number of photolithography steps using masks, thus simplifying the manufacturing process, enhancing the capability of the encapsulation layer of blocking moisture and oxygen, and thereby reducing the risk of decreased light emission efficiency or failure of the OLED device. Moreover, a corresponding color filter piece is formed in each first groove, thereby limiting the flow of the color filter material by the first groove to ensure the shape stability of the color filter piece and reduce the risk of deformation. Especially in the case where the plurality of color filter pieces respectively extend to the non-aperture region to form a plurality of extension pieces which are stacked to form the light-shielding piece, the function of the first groove reduces the non-uniformity at the edge positions of the color filter pieces caused by the edge effect. Moreover, by forming grooves in the encapsulation layer, the thickness of the encapsulation layer at each aperture region becomes thinner, which facilitates light emission and positions each light-shielding piece farther away from the corresponding light-emitting element, thereby enhancing the light-shielding capability and further improving the display effect of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a top-view schematic diagram of a display panel according to a first embodiment of the present application.

FIG. 2 is a cross-sectional schematic diagram taken along cutting line AA in FIG. 1.

FIG. 3 is a schematic diagram of a first groove according to the present application.

FIG. 4 is a schematic diagram of another display panel according to the first embodiment of the present application.

FIG. 5 is a top-view schematic diagram of a display panel according to a second embodiment of the present application.

FIG. 6 is a cross-sectional diagram of the display panel according to the second embodiment of the present application.

FIG. 7 is a schematic diagram of a display device according to the present application.

In the drawings: 100, display panel; 101, aperture region; 102, non-aperture region; 110, substrate; 111, pixel driving layer; 112, pixel defining layer; 113, light-emitting element; 120, encapsulation layer; 121, first inorganic layer; 122, organic encapsulation layer; 123, second inorganic layer; 124, first groove; 125, second groove; 130, color filter layer; 140, color filter piece; 141, first color filter piece; 142, second color filter piece; 143, first color extension piece; 144, second color extension piece; R, red filter piece; B, blue filter piece; RE, red extension piece; BE, blue extension piece; 150, light-shielding piece; 160, touch wiring layer; 170, reflective layer; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

As used herein, an “inverted trapezoidal structure” refers to a trapezoidal structure that is wider at the top and narrower at the bottom, i.e., a structure that gradually tapers from the upper portion to the lower portion and forms an overall inverted trapezoid. This structure may be applied to various layers or components to achieve specific optical, mechanical, or process-related properties.

The present application will be described in detail below with reference to the accompanying drawings and some optional embodiments.

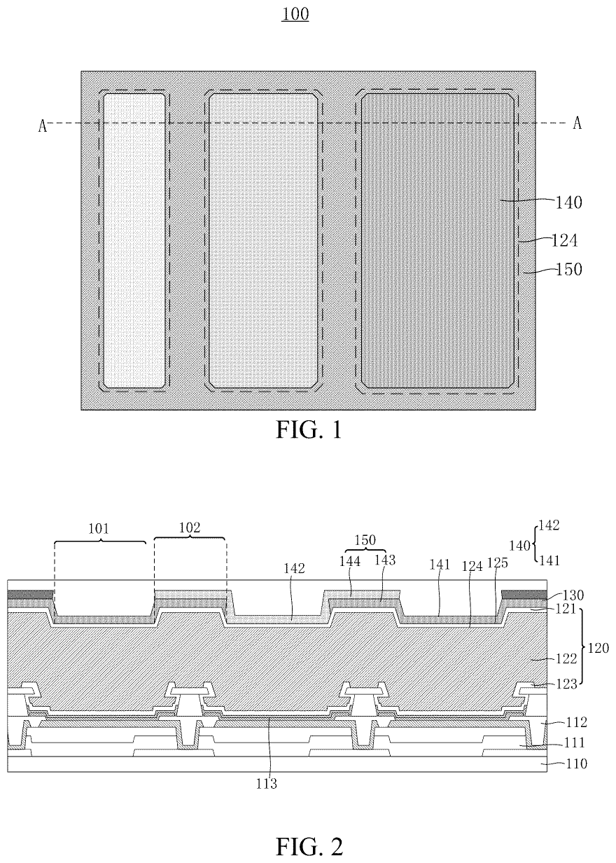

FIG. 1 is a top-view schematic diagram of a display panel according to a first embodiment of the present application. FIG. 2 is a cross-sectional schematic diagram taken along cutting line AA of FIG. 1. Referring to FIGS. 1 and 2, the present application discloses a display panel 100. The display panel 100 includes a substrate 110, a pixel driving layer 111, a pixel defining layer 112, a plurality of light-emitting elements 113, an encapsulation layer 120, and a color filter layer 130. The pixel driving layer 111 is disposed on the substrate 110. The pixel defining layer 112 is disposed on the pixel driving layer 111 and defines a plurality of aperture regions 101. The plurality of light-emitting elements 113 are arranged in an array on the pixel driving layer 111 and are respectively located within the plurality of aperture regions 101. The encapsulation layer 120 is disposed on the plurality of light-emitting elements 113 and is configured to seal the plurality of light-emitting elements 113. The color filter layer 130 is disposed on the encapsulation layer 120. The encapsulation layer 120 defines a first groove 124 at a position corresponding to each aperture region 101. The color filter layer 130 includes a plurality of color filter pieces 140 and a plurality of light-shielding pieces 150. Each of the color filter pieces 140 is disposed in the corresponding first groove 124. The plurality of color filter pieces 140 include color filter pieces 140 of at least two different colors. The plurality of light-shielding pieces 150 are respectively disposed in the plurality of non-aperture regions 102. Each of the light-shielding pieces 150 is formed by overlapping the color filter pieces 140 of different colors.

In the present application, a first groove 124 is formed in the encapsulation layer 120, and the color filter piece 140 is recessed into the first groove 124, that is, the color filter piece 140 is formed within the first groove 124. The plurality of color filter pieces 140 are respectively extended to the non-aperture region 102 to form a plurality of extension pieces, which are stacked together to serve as the light-shielding piece 150. In other words, the light-shielding piece 150 is formed by stacking extension pieces of at least two different colors. This saves the manufacturing procedures required for forming a black matrix, reduces the number of photolithography procedures using masks thereby simplifying the manufacturing process, enhances the ability of the encapsulation layer 120 to block moisture and oxygen thus reducing the risk of decreased light emission efficiency or failure of the OLED device. Moreover, by forming the corresponding color filter piece 140 in each first groove 124, the first groove 124 confines the flow of the corresponding color filter material, thereby ensuring the shape stability of the color filter piece 140 and reducing the risk of deformation. In particular, in the case where the plurality of color filter pieces 140 respectively extend into the non-aperture region 102 to form a plurality of extension pieces that are stacked to form the light-shielding piece 150, the first groove 124 reduces the non-uniformity of the color filter pieces 140 at the edge regions caused by the edge effect. Moreover, by forming grooves in the encapsulation layer 120, the thickness of the encapsulation layer 120 at each aperture region 101 is reduced, which is beneficial for light emission. Additionally, each light-shielding piece 150 is positioned further away from the corresponding light-emitting element 113, thereby enhancing the light-shielding capability and further improving the display effect of the display panel 100.

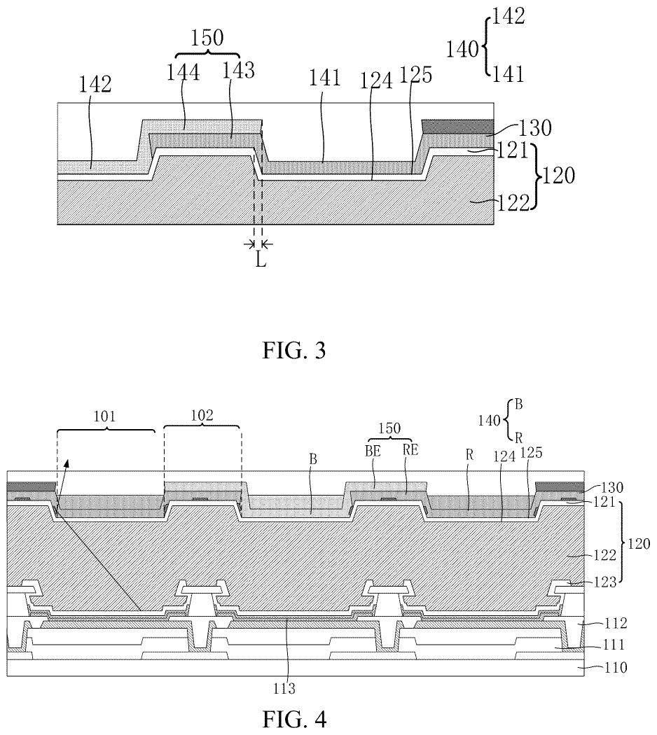

FIG. 3 is a schematic diagram of a first groove according to the present application. Referring to FIG. 3, the encapsulation layer 120 includes an organic encapsulation layer 122. The organic encapsulation layer 122 defines a first groove 124 at a position corresponding to each aperture region 101. The encapsulation layer 120 further includes a first inorganic layer 121. The first inorganic layer 121 is disposed on the organic encapsulation layer 122, and covers each first groove 124 to form the second groove 125.

In this embodiment, the encapsulation layer 120 employs thin-film encapsulation technology, which uses a stack of multiple film layers to achieve encapsulation. In addition to the first inorganic layer 121, a second inorganic layer 123 may be disposed below the organic encapsulation layer 122 (not shown in FIG. 3, refer to FIG. 2), thereby forming a three-layer film stack for encapsulation. The first inorganic layer 121 and the second inorganic layer 123 are formed of an inorganic insulating material. The organic encapsulation layer 122 is formed of an organic insulating material. The first inorganic layer 121 and the second inorganic layer 123 have relatively strong densification performance, and so are capable of blocking moisture and oxygen. The organic encapsulation layer 122 has a relatively greater thickness and possesses better buffering capability. That is, by sequentially forming the second inorganic layer 123, the organic encapsulation layer 122, and the first inorganic layer 121 on the plurality of light-emitting elements 113 (see FIG. 2), the encapsulation of the plurality of light-emitting elements 113 is achieved.

In this embodiment, the first groove 124 is defined in the organic encapsulation layer 122. On one hand, since the thickness of the organic encapsulation layer 122 is relatively thick, forming the first groove 124 in the organic encapsulation layer 122 has minimal impact on the organic encapsulation layer 122 and other film layers. On the other hand, by reducing the thickness of the organic encapsulation layer 122 located at each aperture region 101, the loss of light passing through the organic encapsulation layer 122 may also be reduced.

The thickness of the first inorganic layer 121 is less than the depth of the first groove 124. The thickness of the second inorganic layer 123 is relatively small, having little effect on the depths of the first groove 124 and the second groove 125. It can be considered that the depths of the first groove 124 and the second groove 125 are substantially consistent. Of course, because the thickness of the first inorganic layer 121 is small, the width of the second groove 125 may also be regarded as approximately equal to that of the first groove 124. In fact, the width of the second groove 125 is slightly smaller than that of the first groove 124.

Specifically, the depth of the second groove 125 needs to be greater than or equal to the thickness of the color filter piece 140. When the thicknesses of color filter pieces 140 of different colors vary, the depth of the second groove 125 needs to be greater than or equal to the color filter piece 140 having a color that is the thickest. By configuring the depth of the second groove 125 to be relatively large, when forming the color filter piece 140 and the extension piece located in the non-aperture region 102, the color filter material formed on the sidewall of the second groove 125 becomes more uniform. This prevents issues that occur when the groove beneath the color filter piece 140 is shallow, such as at the overlapping area of the thin black matrix and the color filter piece 140. Due to the thin thickness of the black matrix, part of the film layer of the color filter piece 140 may be pushed up by the black matrix, causing the occurrence of the “horn” phenomenon. The present application avoids the aforementioned “horn” phenomenon by increasing the depth of the second groove 125.

Specifically, the radial width of the first groove 124 is greater than the radial width of the aperture region 101. The orthographic projection of the light-shielding piece 150 on the substrate 110 partially overlaps the orthographic projection of the adjacent first groove 124 on the substrate 110.

In this embodiment, the area of the first groove 124 is larger than the area of the corresponding aperture region 101, that is, the sidewall of the second groove 125 protrudes beyond the edge position of the corresponding aperture region 101. The protruding portion is also covered by the light-shielding piece 150, thereby utilizing the light-shielding capability of the light-shielding piece 150 to restrict light emission from the portion of the first groove 124 located within the non-aperture region 102. It can be understood that, each aperture region 101 may correspond to the effective light-emitting area of each light-emitting element 113 or the aperture region disposed on the pixel defining layer 112. No light-shielding piece 150 is arranged within each aperture region 101 in the present application. That is, the regions without the light-shielding piece 150 are the aperture regions 101, and the regions having the light-shielding piece 150 are the non-aperture regions 102. In this embodiment, the first groove 124 extends from the aperture region 101 toward the non-aperture region 102, so that part of the light-shielding piece 150 covers the color filter piece 140 within the adjacent first groove 124, thereby covering the region where the layer of the color filter piece 140 changes abruptly.

The distance L between the sidewall of the second groove 125 and the edge of the corresponding aperture region 101 is 5 μm to 20 μm. By extending the second groove 125 toward the non-aperture region 102, the sidewall of the second groove 125 extends beyond the edge of the corresponding aperture region 101 by at least 5 μm. When forming the light-shielding piece 150 in each non-aperture region 102, the light-shielding piece 150 can avoid blocking the light from the corresponding aperture region 101 as much as possible.

FIG. 4 is a schematic diagram of another display panel of the first embodiment of the present application. Referring to FIG. 4 and also referring to FIG. 3, the plurality of color filter pieces 140 include a plurality of first color filter pieces 141 and a plurality of second color filter pieces 142. The plurality of first color filter pieces 141 has a different color than that of the plurality of second color filter pieces 142. In each non-aperture region 102, a first color extension piece 143 is formed synchronously with the first color filter pieces 141, and a second color extension piece 144 is formed synchronously with the second color filter pieces 142. The first color extension piece 143 and the second color extension piece 144 are stacked to form the light-shielding piece 150. The first color filter piece 141 is a red filter piece R. The first color extension piece 143 is a red extension piece RE. The second color filter piece 142 is a blue filter piece B. The second color extension piece 144 is a blue extension piece BE. In each non-aperture region 102, the light-shielding piece 150 is formed by stacking the red extension piece RE and the blue extension piece BE.

When the light-shielding pieces 150 of the display panel 100 are each formed by the red extension piece RE and the blue extension piece BE, during the formation of the red filter piece R, the red extension piece in each non-aperture region 102 needs to be retained. That is, all red extension pieces RE not located in the second grooves 125 are retained. During the formation of the blue filter piece B, the blue extension piece in each non-aperture region 102 needs to be retained. That is, all blue extension pieces BE not located in the second grooves 125 are retained. That is, the light-shielding piece 150 is formed by using the red extension piece RE and the blue extension piece BE. The advantage is that the blue filter piece B and the red filter piece R are respectively located at the shorter and longer wavelength ends, with a large wavelength difference and no overlapping wavelength region between them, resulting in better light-shielding capability. It is worth mentioning that the fabrication of the black matrix and color filter pieces 140 of different colors requires multiple photolithography procedures using masks, resulting in a complex manufacturing process. Moreover, multiple wet procedures and baking procedures increase the stress on the capability of the encapsulation layer 120 of blocking moisture and oxygen, thereby increasing the risk of reduced OLED device light emission efficiency or device failure. In this embodiment, the light-shielding piece 150 is formed by stacking color filter piece materials, thereby addressing the above-mentioned issues.

Of course, considering that the color filter pieces 140 of the display panel 100 may include red filter pieces R, blue filter pieces B, and green filter pieces, that is, the plurality of color filter pieces 140 include a plurality of red filter pieces R, a plurality of blue filter pieces B, and a plurality of green filter pieces. In each of the non-aperture regions 102, a red extension piece RE is formed synchronously with the red filter piece R, a green extension piece is formed synchronously with the green filter piece, and a blue extension piece BE is formed synchronously with the blue filter piece B. Two selected from the red extension piece RE, the green extension piece, and the blue extension piece BE are stacked in each non-aperture region 102 to form the light-shielding piece 150.

In this embodiment, considering the display panel 100, one red filter piece R, one blue filter piece B, and one green filter piece adjacent to each other may form a pixel. The red filter piece R can serve as a red sub-pixel, the blue filter piece B can serve as a blue sub-pixel, and the green filter piece can serve as a green sub-pixel, thereby forming a pixel for display through the red sub-pixel, blue sub-pixel, and green sub-pixel.

The light-shielding piece 150 between the red sub-pixel and the blue sub-pixel may be formed by stacking the red extension piece RE and the blue extension piece BE. The light-shielding piece 150 between the red sub-pixel and the green sub-pixel may be formed by stacking the red extension piece RE and the blue extension piece BE, or by stacking the red extension piece RE and the green extension piece. The light-shielding piece 150 between the blue sub-pixel and the green sub-pixel may be formed by stacking the red extension piece RE and the blue extension piece BE, or by stacking the blue extension piece BE and the green extension piece.

Specifically, each color filter piece 140 may be formed using a photoresist material. During the formation process, after pre-curing, photolithography using a mask is performed to retain the color filter piece 140 in each aperture region 101 and remove the color filter piece 140 in each non-aperture region 102, followed by post-curing to achieve patterned plurality of color filter pieces 140.

In this embodiment, a first layer of color filter piece 140 with a thickness corresponding to that of the respective color extension piece can be formed first. After completing the manufacturing procedure of the light-shielding piece 150, a second layer of color filter piece 140 may then be formed respectively in each aperture region 101 to form the required plurality of color filter pieces 140. Even when the light-shielding piece 150 is arranged in a stacked manner, the required thickness of each of the color extension pieces may not need to be very thick. However, the color filter piece 140 requires higher color fidelity, and its light-filtering capability is related to its thickness. Therefore, a certain thickness of the color filter piece 140 is needed to enhance the light-filtering capability, improve the color accuracy, and achieve a better display effect of the display panel 100.

In this embodiment, the plurality of color filter pieces 140 of each color can be formed in two steps. Specifically, the manufacturing procedure of the plurality of color filter pieces of the same color can be carried out in two sequential steps. For example, first forming a color filter piece 140 and a color extension piece with a first thickness, performing pre-curing and patterning, then forming a second thickness of the color filter piece 140, followed by another patterning and curing, thereby forming a color filter piece 140 with a thickness greater than that of the corresponding color extension piece. After completing the manufacturing procedures, the thickness of the red extension piece RE may be equal to half of the thickness of the red filter piece R, and the thickness of the blue extension piece BE may be equal to half of the thickness of the blue filter piece B. Of course, the thickness of each color filter piece 140 corresponding to each second groove 125 can also be made greater than the thickness of the corresponding color extension piece by adjusting the fluidity of the photoresist material. When using the stacked extension pieces of adjacent color filter pieces 140 as the light-shielding piece 150, the thickness design can be consistent with that of the present embodiment.

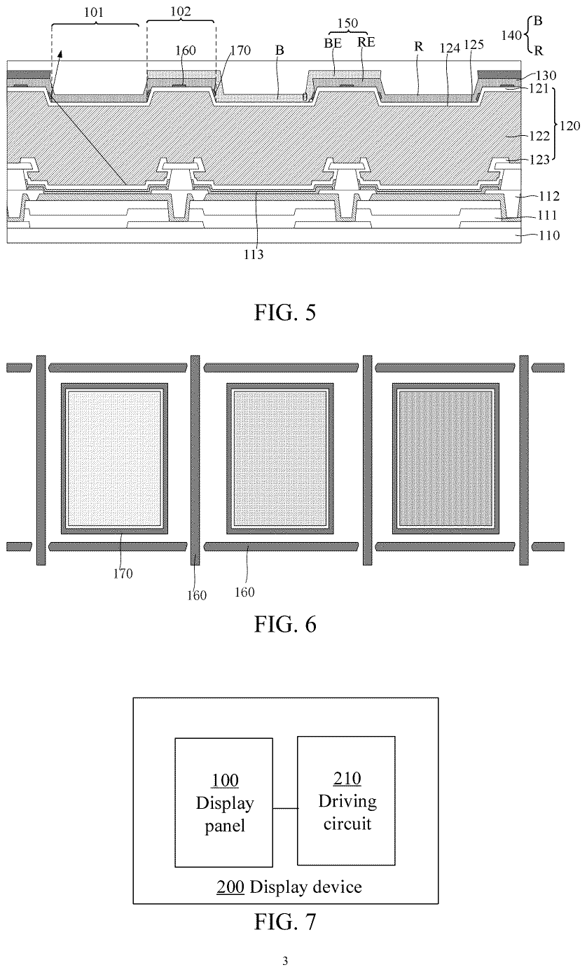

FIG. 5 is a top-view schematic diagram of a display panel according to a second embodiment of the present application. FIG. 6 is a cross-sectional view of a display panel according to the second embodiment of the present application. Referring to FIGS. 5 to 6, the present application discloses another display panel 100. In this embodiment, the display panel 100 further includes a reflective layer 170 based on the foregoing embodiment, which enhances the light output efficiency through the reflective layer 170. Specifically, the display panel 100 further includes a plurality of reflective layers 170. Each of the reflective layers 170 is disposed on the side surface of the corresponding first groove 124. Each of the reflective layers 170 forms an obtuse angle θ with the bottom surface of the corresponding first groove 124. Moreover, each of the reflective layers 170 is disposed in the corresponding non-aperture region 102.

Specifically, when the first inorganic layer 121 is disposed on the organic encapsulation layer 122, the reflective layer 170 may be disposed on the first inorganic layer 121. The reflective layer 170 may be arranged to surround the corresponding aperture region 101. The inclination angle of the reflective layer 170 is consistent with the inclination angle of the sidewall of the corresponding second groove 125. The orthographic projection of each light-shielding piece 150 on the substrate 110 partially overlaps the orthographic projection of the corresponding second groove 125 on the substrate 110. Each sidewall of the second groove 125 is spaced from the edge of the corresponding aperture region 101 by 5 μm to 20 μm. By extending each second groove 125 toward the adjacent non-aperture region 102, the sidewall of the second groove 125 protrudes beyond the edge of the corresponding aperture region 101 by at least 5 μm.

In this embodiment, the reflective layer 170 is arranged on the sidewall of each second groove 125. During the formation of the first groove 124, the bottom surface and the side surface of the first groove 124 form an obtuse angle, such that the inclination angle of the reflective layer 170 is consistent with the inclination angle of the sidewall of the first groove 124. Within each aperture region 101, the corresponding reflective layer 170 can reflect part of the light emitted from the corresponding light-emitting element 113 toward the light-shielding piece 150, thereby improving the light output efficiency of the corresponding light-emitting element 113.

Specifically, the display panel 100 further includes a touch wiring layer 160, which is disposed on the encapsulation layer 120. The touch wiring layer 160 and the reflective layer 170 are formed of a metal material in the same manufacturing procedure. The touch wiring layer 160 may be disposed on the encapsulation layer 120. In this embodiment, the reflective layer 170 can be formed simultaneously while forming the touch wiring layer 160. The touch wiring layer 160 may be formed of a metal material, which may have superior reflective properties and can block the light emitted from each light-emitting element 113 toward the corresponding light-shielding piece 150, thereby improving the light output efficiency of the display panel 100.

In another embodiment, the touch wiring layer 160 may be reused as the reflective layer 170. That is, when forming the touch wiring layer 160, part of the touch wiring layer 160 is disposed on the sidewall of each second groove 125, thereby achieving the function of reflecting light.

After disposing the reflective layer 170, when external ambient light enters the interior of the display panel 100, some light may also be incident on the reflective layer 170. To address this, the present application improves the light-shielding piece 150 such that the orthographic projection of the light-shielding piece 150 on the substrate 110 overlaps the orthographic projection of the reflective layer 170 on the substrate 110.

Specifically, the plurality of color filter pieces 140 include a plurality of first color filter pieces 141 and a plurality of second color filter pieces 142. The color of the plurality of first color filter pieces 141 differs from that of the plurality of second color filter pieces 142. In each non-aperture region 102, a first color extension piece 143 is formed synchronously with the plurality of first color filter pieces 141, and a second color extension piece 144 is formed synchronously with the plurality of second color filter pieces 142. The first color extension piece 143 and the second color extension piece 144 are stacked to form the light-shielding piece 150. In each non-aperture region 102, the first color extension piece 143 is disposed below the second color extension piece 144. The orthographic projection of the first color extension piece 143 on the substrate 110 overlaps the orthographic projection of the reflective layer 170 on the substrate 110. The orthographic projection of the second color extension piece 144 on the substrate 110 overlaps the orthographic projection of the reflective layer 170 on the substrate 110.

The first color filter piece 141 is a red filter piece R. The first color extension piece 143 is a red extension piece RE. The second color filter piece 142 is a blue filter piece B. The second color extension piece 144 is a blue extension piece BE. In each non-aperture region 102, the light-shielding piece 150 is formed by stacking the red extension piece RE and the blue extension piece BE.

In this embodiment, the red extension piece RE is disposed below the blue extension piece BE. When the reflective layer 170 is disposed on the sidewall of the second groove 125 where the red filter piece R is located, at this time, in addition to the red extension piece RE overlapping with the reflective layer 170, by arranging the blue extension piece BE on the red extension piece RE, the blue extension piece BE also overlaps the reflective layer 170 in the orthographic projection on the substrate 110. This achieves overlap between the light-shielding piece 150 and the reflective layer 170 on the substrate 110, whereby the light-shielding piece 150 blocks the reflective layer 170, thus preventing external ambient light from irradiating the reflective layer 170.

Further, each color filter piece 140 of the present application may be formed using a negative photoresist material. The negative organic photoresist materials include polyimide, epoxy resin, or polyacrylate, etc. The characteristic of such materials is that the irradiated portions undergo polymerization and cross-linking, thus remaining as functional structures, while the unexposed parts of the negative photosensitive organic material are removed by the developer solution in subsequent manufacturing procedures. During photolithography, a layer of negative organic photoresist material is coated on the encapsulation layer 120. Due to the photosensitive property of the negative organic photoresist material, after coating into a film, the exposed portions undergo polymerization and cross-linking. Thus, under illumination, the surface receives stronger light and is more easily polymerized and cross-linked, while the light intensity gradually decreases at deeper regions, resulting in a lower degree of polymer cross-linking than at the surface. Therefore, during the development process, the lower parts with weakened photosensitivity are partially removed, forming an inverted trapezoidal structure that is wider at the top and narrower at the bottom. As a result, the blue extension piece BE has a trapezoidal structure with a wider top and narrower bottom at the end of the red extension piece RE, thereby achieving light shielding of the reflective layer 170.

In this embodiment, the first color extension piece 143 may also be formed using the negative photoresist material. When the first color extension piece 143 is disposed below the second color extension piece 144, the reflective layer 170 disposed on the side of the first color extension piece 143 adjacent to the neighboring second color filter piece 142 also needs to be shielded by the first color extension piece 143. An obtuse angle is formed between a side surface of the first color extension piece 143, which is located on a side adjacent to the second color filter piece 142, and a bottom surface of the first color extension piece 143. That is, an obtuse angle is formed between a side surface of the red extension piece RE, which is located on a side adjacent to the blue filter piece B, and a bottom surface of the red extension piece RE.

Specifically, the light-shielding piece 150 between the red sub-pixel and the blue sub-pixel is formed by stacking the red extension piece RE and the blue extension piece BE. In the case of the display panel 100 in which the light-shielding piece 150 between the red sub-pixel and the green sub-pixel, and the light-shielding piece 150 between the blue sub-pixel and the green sub-pixel, are each formed by stacking the red extension piece RE and the blue extension piece BE, the specific manufacturing procedures include first forming the red filter piece R, and then respectively forming the red extension pieces RE on both sides of the red filter piece R to serve as part of the light-shielding piece 150. Then a green filter piece is formed at the position of the green filter region, and green extension pieces are formed on both sides of the green filter piece. In the present embodiment, since the red sub-pixel is not adjacent to the green sub-pixel, the green extension piece does not overlap the red extension piece RE. Finally, the blue filter piece B is formed, and two blue extension pieces BE are respectively formed on both sides of the blue filter piece B. These two blue extension pieces BE are stacked with the red extension piece RE and the green extension piece, respectively, to form two light-shielding pieces 150. It can be understood that when the arrangement of the red sub-pixel, green sub-pixel, and blue sub-pixel varies, the film layers stacked to form the light-shielding piece 150 can be flexibly selected. For example, the light shielding can be achieved by stacking film layers of two or three colors. When light shielding is required at an intermediate position between two adjacent red sub-pixels, the light-shielding piece 150 may be formed by stacking the red extension piece RE and the blue extension piece BE.

FIG. 7 is a schematic diagram of a display device 200 according to the present application. As shown in FIG. 7, the present application further discloses a display device 200. The display device 200 includes a driving circuit 210 and the display panel 100 according to any one of the above embodiments, where the driving circuit 210 is configured to drive the display panel 100 for display.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising:
a substrate;
a pixel driving layer, disposed on the substrate;
a pixel defining layer, disposed on the pixel driving layer, the pixel defining layer defining a plurality of aperture regions;
a plurality of light-emitting elements, arranged on the pixel driving layer and respectively disposed within the plurality of aperture regions;
an encapsulation layer, disposed on the plurality of light-emitting elements to seal the plurality of light-emitting elements, the encapsulation layer having a first groove at a position corresponding to each of the plurality of aperture regions; and
a color filter layer, disposed on the encapsulation layer;
wherein the color filter layer comprises a plurality of color filter pieces and a plurality of light-shielding pieces, wherein each of the plurality of color filter pieces is disposed in a corresponding first groove, wherein the plurality of color filter pieces comprise color filter pieces of at least two colors, wherein the plurality of light-shielding pieces are respectively disposed in the plurality of non-aperture regions, and wherein each of the plurality of light-shielding pieces is formed by stacking the color filter pieces of different colors.

2. The display panel as recited in claim 1, wherein the encapsulation layer comprises an organic encapsulation layer, and wherein the first groove is disposed at a position corresponding to each of the plurality of aperture regions in the organic encapsulation layer;
wherein a radial width of the first groove is greater than a radial width of the corresponding aperture region;
wherein an orthographic projection of each of the plurality of light-shielding pieces on the substrate partially overlaps an orthographic projection of an adjacent first groove on the substrate.

3. The display panel as recited in claim 2, wherein the encapsulation layer further comprises a first inorganic layer disposed on the organic encapsulation layer, wherein a thickness of the first inorganic layer is less than a depth of the first groove, and wherein the first inorganic layer covers the first groove to form a second groove;
wherein a distance between a sidewall of the second groove and an edge of the corresponding aperture region lies in a range of 5 μm to 20 μm.

4. The display panel as recited in claim 2, wherein an area of an orthographic projection of the first groove on the substrate is greater than an area of an orthographic projection of the corresponding aperture region on the substrate.

5. The display panel as recited in claim 1, wherein the plurality of color filter pieces comprise a plurality of first color filter pieces and a plurality of second color filter pieces; wherein a color of the plurality of first color filter pieces is different from a color of the plurality of second color filter pieces;
wherein in each of the plurality of non-aperture regions, a first color extension piece is formed synchronously with the plurality of first color filter pieces, and a second color extension piece is formed synchronously with the plurality of second color filter pieces, wherein the first color extension piece and the second color extension piece are stacked to form the corresponding light-shielding piece.

6. The display panel as recited in claim 5, wherein each of the plurality of first color filter pieces is a red filter piece, each of the plurality of first color extension pieces is a red extension piece, each of the plurality of second color filter pieces is a blue filter piece, and each of the plurality of second color extension pieces is a blue extension piece;
wherein in each of the plurality of non-aperture regions, the corresponding light-shielding piece is formed by stacking the red extension piece and the blue extension piece.

7. The display panel as recited in claim 1, further comprising a plurality of reflective layers, wherein each of the plurality of reflective layers is disposed on a side surface of a corresponding first groove, and wherein each of the plurality of reflective layers forms an obtuse angle with a bottom surface of the corresponding first groove.

8. The display panel as recited in claim 7, further comprising a touch wiring layer, the touch wiring layer being disposed on the encapsulation layer;
wherein the touch wiring layer and the reflective layer are formed of a metal material in a same manufacturing procedure.

9. The display panel as recited in claim 7, wherein the plurality of color filter pieces comprise a plurality of first color filter pieces and a plurality of second color filter pieces; wherein a color of the plurality of first color filter pieces is different from a color of the plurality of second color filter pieces;
wherein in each of the plurality of non-aperture regions, a first color extension piece is formed synchronously with the plurality of first color filter pieces, and a second color extension piece is formed synchronously with the plurality of second color filter pieces, wherein the first color extension piece and the second color extension piece are stacked to form the corresponding light-shielding piece;
wherein the first color extension piece is disposed below the second color extension piece, and an orthographic projection of each of the second color extension piece and the second color extension piece on the substrate partially overlaps an orthogonal projection of the corresponding reflective layer on the substrate;
wherein the plurality of reflective layers are respectively disposed in the plurality of non-aperture regions.

10. The display panel as recited in claim 9, wherein each of the plurality of first color filter pieces is a red filter piece, each of the plurality of first color extension pieces is a red extension piece, each of the plurality of second color filter pieces is a blue filter piece, and each of the plurality of second color extension pieces is a blue extension piece;
wherein in each of the plurality of non-aperture regions, the corresponding light-shielding piece is formed by stacking the red extension piece and the blue extension piece.

11. The display panel as recited in claim 10, wherein a thickness of each red extension piece is equal to half of a thickness of each red filter piece, and wherein a thickness of each blue extension piece is equal to half of a thickness of each blue filter piece.

12. The display panel as recited in claim 9, wherein a side surface of each of the plurality of first color extension pieces adjacent to a neighboring second color filter piece forms an obtuse angle with a bottom surface of the first color extension piece.

13. The display panel as recited in claim 7, wherein the encapsulation layer comprises an organic encapsulation layer and a first inorganic layer, wherein the first groove is disposed at a position corresponding to each of the plurality of aperture regions in the organic encapsulation layer;
wherein the first inorganic layer is disposed on the organic encapsulation layer, wherein a thickness of the first inorganic layer is less than a depth of the first groove, and wherein the first inorganic layer covers the first groove to form a second groove;
wherein the plurality of reflective layers are disposed on the first inorganic layer, each reflective layer being arranged to surround a corresponding aperture region.

14. A display device, comprising a driving circuit and a display panel, wherein the driving circuit is configured to drive the display panel for display, wherein the display panel comprises:
a substrate;
a pixel driving layer, disposed on the substrate;
a pixel defining layer, disposed on the pixel driving layer, the pixel defining layer defining a plurality of aperture regions;
a plurality of light-emitting elements, arranged on the pixel driving layer and respectively disposed within the plurality of aperture regions;
an encapsulation layer, disposed on the plurality of light-emitting elements to seal the plurality of light-emitting elements, the encapsulation layer having a first groove at a position corresponding to each of the plurality of aperture regions; and
a color filter layer, disposed on the encapsulation layer;
wherein the color filter layer comprises a plurality of color filter pieces and a plurality of light-shielding pieces, wherein each of the plurality of color filter pieces is disposed in a corresponding first groove, wherein the plurality of color filter pieces comprise color filter pieces of at least two colors, wherein the plurality of light-shielding pieces are respectively disposed in the plurality of non-aperture regions, and wherein each of the plurality of light-shielding pieces is formed by stacking the color filter pieces of different colors.

15. The display device as recited in claim 14, wherein the encapsulation layer comprises an organic encapsulation layer, and wherein the first groove is disposed at a position corresponding to each of the plurality of aperture regions in the organic encapsulation layer;
wherein a radial width of the first groove is greater than a radial width of the corresponding aperture region;
wherein an orthographic projection of each of the plurality of light-shielding pieces on the substrate partially overlaps an orthographic projection of an adjacent first groove on the substrate.

16. The display device as recited in claim 15, wherein the encapsulation layer further comprises a first inorganic layer disposed on the organic encapsulation layer, wherein a thickness of the first inorganic layer is less than a depth of the first groove, and wherein the first inorganic layer covers the first groove to form a second groove;
wherein a distance between a sidewall of the second groove and an edge of the corresponding aperture region lies in a range of 5 μm to 20 μm.

17. The display device as recited in claim 14, wherein the display panel further comprises a plurality of reflective layers, wherein each of the plurality of reflective layers is disposed on a side surface of a corresponding first groove, and wherein each of the plurality of reflective layers forms an obtuse angle with a bottom surface of the corresponding first groove.

18. The display device as recited in claim 17, wherein the display panel further comprises a touch wiring layer, the touch wiring layer being disposed on the encapsulation layer;
wherein the touch wiring layer and the reflective layer are formed of a metal material in a same manufacturing procedure.

19. The display device as recited in claim 17, wherein the plurality of color filter pieces comprise a plurality of first color filter pieces and a plurality of second color filter pieces; wherein a color of the plurality of first color filter pieces is different from a color of the plurality of second color filter pieces;
wherein in each of the plurality of non-aperture regions, a first color extension piece is formed synchronously with the plurality of first color filter pieces, and a second color extension piece is formed synchronously with the plurality of second color filter pieces, wherein the first color extension piece and the second color extension piece are stacked to form the corresponding light-shielding piece;
wherein the first color extension piece is disposed below the second color extension piece, and an orthographic projection of each of the second color extension piece and the second color extension piece on the substrate partially overlaps an orthogonal projection of the corresponding reflective layer on the substrate;
wherein the plurality of reflective layers are respectively disposed in the plurality of non-aperture regions.

20. The display device as recited in claim 19, wherein each of the plurality of first color filter pieces is a red filter piece, each of the plurality of first color extension pieces is a red extension piece, each of the plurality of second color filter pieces is a blue filter piece, and each of the plurality of second color extension pieces is a blue extension piece;
wherein in each of the plurality of non-aperture regions, the corresponding light-shielding piece is formed by stacking the red extension piece and the blue extension piece.
